(19) United States
(12) Patent Application Publication
(10) Pub. No.: US 2024/0222446 A1
(43) Pub. Date: Jul. 4, 2024

(54) THIN FILM TRANSISTOR AND ELECTRONIC DEVICE

(71) Applicant: WUHAN CHINA STAR OPTOELECTRONICS TECHNOLOGY CO., LTD., Wuhan, Hubei (CN)

(72) Inventors: Fei Ai, Wuhan, Hubei (CN); Dewei Song, Wuhan, Hubei (CN)

(73) Assignee: WUHAN CHINA STAR OPTOELECTRONICS TECHNOLOGY CO., LTD., Wuhan, Hubei (CN)

(21) Appl. No.: 17/996,787

(22) PCT Filed: Aug. 30, 2022
(86) PCT No.: PCT/CN2022/115992

§ 371 Date: Oct. 20, 2022

(30) Foreign Application Priority Data
Aug. 10, 2022 (CN) 202210954593.X

(51) Int. Cl. H01L 29/417; H01L 29/08; H01L 29/49; H01L 29/66; H01L 29/786

(52) U.S. Cl. CPC H01L 29/41733; H01L 29/0847; H01L 29/4908; H01L 29/66757; H01L 29/66969; H01L 29/78675; H01L 29/7869

(57) ABSTRACT

The present application provides a thin film transistor and an electronic device. The thin film transistor includes: a crystalline active pattern, wherein the crystalline active pattern includes a channel and two contact portions, and the two contact portions are connected to opposite two sides of the channel in a direction intersecting a thickness direction of the crystalline active pattern; a groove located on at least one of the two contact portions and extending in the thickness direction of the crystalline active pattern; a source electrode and a drain electrode connected to the two contact portions, respectively; and an insulating layer being in contact with the channel.

### BACKGROUND OF INVENTION

### Field of Invention

The present application relates to a field of display technology, and specifically to a thin film transistor and an electronic device.

### Description of Prior Art

Integrating integrated circuits on a glass substrate (system on glass (SOG)) can greatly improve an integration degree of display panels and reduce manufacturing cost of the display panels. However, it is necessary to improve mobility of thin film transistors to realize the integration of the integrated circuits on the glass substrate.

Therefore, how to improve the mobility of the thin film transistors is a technical problem to be solved.

### SUMMARY OF INVENTION

A purpose of the present application is to provide a thin film transistor and an electronic device, which is conducive to improving mobility of thin film transistors.

To achieve the above purpose, technical schemes are as follows:

A thin film transistor, wherein the thin film transistor includes:
a crystalline active pattern, wherein the crystalline active pattern includes:
a channel;
two contact portions, the two contact portions connected to opposite two sides of the channel in a direction intersecting a thickness direction of the crystalline active pattern; and
at least one groove located on at least one of the two contact portions and extending in the thickness direction of the crystalline active pattern;
a source electrode and a drain electrode connected to the two contact portions, respectively; and
a heat-retaining layer, the heat-retaining layer being in contact with the channel.

In thin film transistors of some embodiments, the crystalline active pattern further includes two transition portions, one of the transition portions is connected between one of the contact portions and the channel, and the heat-retaining layer is further in contact with the two transition portions.

In thin film transistors of some embodiments, the crystalline active pattern includes crystalline grains having sizes greater than or equal to 300 nm.

In thin film transistors of some embodiments, a refractive index of the heat-retaining layer is defined as n, a thickness of the heat-retaining layer is defined as d, and the n, the d, and a wavelength λ of laser satisfy a following formula:

2d×n=k×λ, wherein the k is an integer greater than or equal to 1, and the wavelength λ of the laser is greater than or equal to 180 nm and is less than or equal to 420 nm.

In thin film transistors of some embodiments, a thickness of the heat-retaining layer is greater than or equal to 100 Å and is less than or equal to 1000 Å.

In thin film transistors of some embodiments, a depth of the groove is less than or equal to a thickness of the crystalline active pattern, and the groove is located at a position of at least one of the contact portions adjacent to the channel.

In thin film transistors of some embodiments, a depth of the groove is less than a thickness of the crystalline active pattern, and one groove located on one of the contact portions completely overlaps the one of the contact portions.

In thin film transistors of some embodiments, the thin film transistor further includes:
a gate electrode disposed corresponding to the channel;
a gate insulating layer located between the gate electrode and the crystalline active pattern;
an interlayer insulating layer located between the crystalline active pattern and the source electrode and between the crystalline active pattern and the drain electrode; and
two contact holes at least penetrating the interlayer insulating layer, and the source electrode and the drain electrode being connected to the two contact portions through the two contact holes, respectively.

In thin film transistors of some embodiments, the gate electrode is located between the crystalline active pattern and the source electrode and between the crystalline active pattern and the drain electrode, and the interlayer insulating layer is located between the gate electrode and the source electrode and between the gate electrode and the drain electrode; and
the two contact holes further penetrate the gate insulating layer, at least one of the two contact holes overlaps the groove, and an aperture of each of the contact hole is greater than an opening size of the groove.

An electronic device, wherein the electronic device includes the thin film transistor according to any one of the above embodiments.

Beneficial effects: the present application provides the thin film transistor and the electronic device, by defining the groove in at least one of the two contact portions of the crystalline active pattern, it is conducive to forming seed crystals at a position where the groove is located during a process of crystallization to form the crystalline active pattern. Wherein the seed crystals grow toward the channel before crystallization and cooperate with the heat-retaining layer to make heat dissipation of a pre-crystallization channel slower, so as to form large-sized crystalline grains in the channel, thereby reducing crystalline boundaries in the channel of the crystalline active pattern, so as to improve the mobility of the thin film transistor.

### BRIEF DESCRIPTION OF DRAWINGS

FIG. 1 is a planar schematic diagram of an array substrate of an embodiment of the present application.

FIG. 2 is a cross-sectional schematic diagram taken along a line A-A defined in the array substrate shown in FIG. 1.

FIG. 3 is a cross-sectional schematic diagram taken along a line B-B defined in the array substrate shown in FIG. 1.

FIG. 4 is a cross-sectional schematic diagram of an array substrate of another embodiment of the present application.

FIG. 5 is a planar schematic diagram of a crystalline active pattern in FIG. 4.

FIG. 6 is a cross-sectional schematic diagram of an array substrate of yet another embodiment of the present application.

FIG. 7A-FIG. 7J are schematic diagrams of a process of manufacturing the array substrate of an embodiment of the present application.

FIG. 8 is a cross-sectional schematic diagram of an electronic device of an embodiment of the present application.

### DETAILED DESCRIPTION OF EMBODIMENTS

Technical schemes in embodiments of the present application will be clearly and completely described below in combination with drawings in the embodiments of the present application. Obviously, the described embodiments are only part of the embodiments of the present application, not all of the embodiments. Based on the embodiments in the present application, all other embodiments obtained by those skilled in the art without making creative labor fall within a scope of protection of the present application.

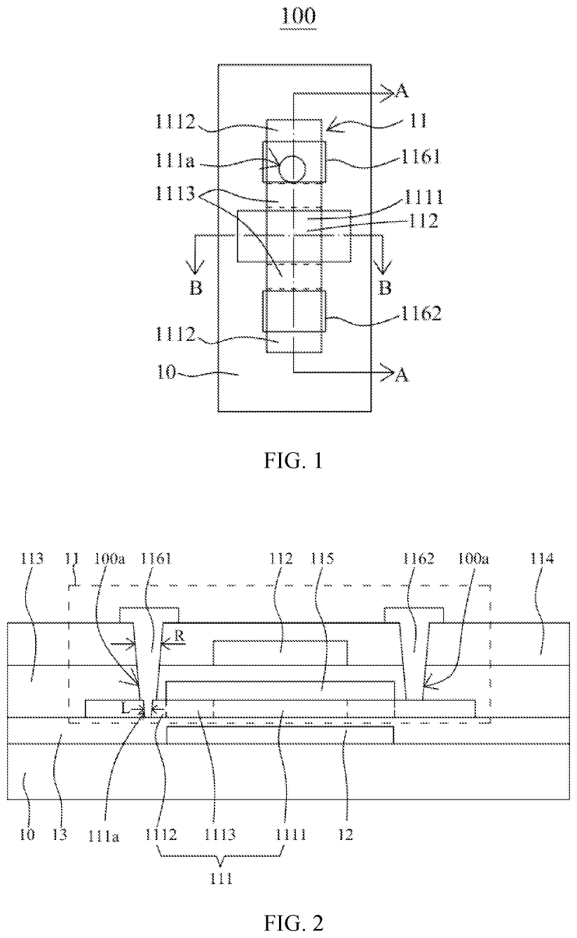

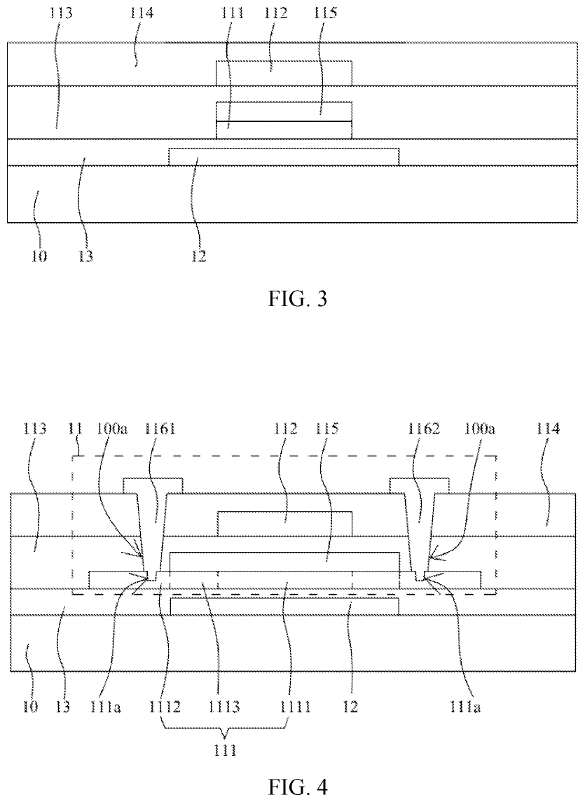

Please refer to FIG. 1, FIG. 2, and FIG. 3. FIG. 1 is a planar schematic diagram of an array substrate of an embodiment of the present application, FIG. 2 is a cross-sectional schematic diagram taken along a line A-A defined in the array substrate shown in FIG. 1, and FIG. 3 is a cross-sectional schematic diagram taken along a line B-B defined in the array substrate shown in FIG. 1.

In this embodiment, the array substrate 100 includes a substrate 10 and a plurality of thin film transistors 11 arranged in an array on the substrate 10. The substrate 10 is an insulating substrate, such as a glass substrate, but is not limited thereto. The substrate 10 can also be a flexible substrate. The thin film transistors 11 are low-temperature polysilicon thin film transistors, but are not limited thereto. The thin film transistors 11 can also be crystalline metal oxide thin film transistors.

In this embodiment, the array substrate 100 further includes a light-shielding pattern 12 and a buffer layer 13. The light-shielding pattern 12 is located between the thin film transistors 11 and the substrate 10, and the buffer layer 13 is located between the light-shielding pattern 12 and the thin film transistors 11.

In this embodiment, the light-shielding pattern 12 is disposed on the substrate 10 in a flat state. A preparation material of the light-shielding pattern 12 includes at least one of metal and black organic materials.

In this embodiment, the buffer layer 13 covers the light-shielding pattern 12 and the substrate 10. A preparation material of the buffer layer 13 includes at least one of silicon nitride and silicon oxide. A thickness of the buffer layer 13 is greater than or equal to 2500 Å and is less than or equal to 3500 Å; for example, the thickness of the buffer layer 13 can be 2500 Å, 2800 Å, 3000 Å, or 3500 Å.

In this embodiment, the thin film transistor 11 includes a crystalline active pattern 111, a gate electrode 112, a source electrode 1161, a drain electrode 1162, a gate insulating layer 113, an interlayer insulating layer 114, and a heat-retaining layer 115.

In this embodiment, the crystalline active pattern 111 is a low-temperature polysilicon active pattern, but it is not limited thereto. The crystalline active pattern 111 can also be a crystalline metal oxide active pattern. A thickness of the crystalline active pattern 111 is greater than or equal to 300 Å and is less than or equal to 600 Å; for example, the thickness of the crystalline active pattern 111 can be 350 Å, 380 Å, 400 Å, 420 Å, 450 Å, 480 Å, 500 Å, or 600 Å.

In this embodiment, the crystalline active pattern 111 is disposed on the buffer layer 13. The crystalline active pattern 111 includes a channel 1111, two contact portions 1112, and two transition portions 1113. In a direction intersecting a thickness direction of the crystalline active pattern 111, the two contact portions 1112 are connected to opposite two sides of the channel 1111, and one of the transition portions 1113 is connected between one of the contact portions 1112 and the channel 1111.

Specifically, in a direction perpendicular to the thickness of the crystalline active pattern 111, the two contact portions 1112 are connected to the opposite two sides of the channel 1111, respectively, and one of the transition portions 1113 is connected between one of the contact portions 1112 and the channel 1111. The channel 1111 and the two transition portions 1113 all overlap the light-shielding pattern 12, so that the light-shielding pattern 12 plays a light shielding role against light incident on the channel 1111 and the two transition portions 1113.

It should be noted that the channel 1111 is not doped with ions, the two contact portions 1112 and the two transition portions 1113 are all doped with ions, and an ion doping concentration of the two transition portions 1113 is less than an ion doping concentration of the two contact portions 1112.

In this embodiment, the crystalline active pattern 111 further includes a groove 111a, the groove 111a is located in at least one of the two contact portions 1112. The groove 111a is located on a side of the contact portions 1112 away from the substrate 10, and extends in the thickness direction of the crystalline active pattern 111; a depth of the groove 111a is less than or equal to the thickness of the crystalline active pattern 111.

It can be understood that the groove 111a can be defined in one of the contact portions 1112, or in the two contact portions 1112. Each of the contact portions 1112 can be defined with one, two, or more grooves 111a. The depth of the groove 111a can be equal to the thickness of the crystalline active pattern 111, or the depth of the groove 111a can be less than the thickness of the crystalline active pattern 111.

In this embodiment, the groove 111a is located at a position of at least one of the contact portions 1112 adjacent to the channel 1111. In other words, the groove 111a is located at a part of a position where a contact portion 1112 is located, and the groove 111a is defined close to the transition portions 1113.

A design of the groove of the crystalline active pattern in the embodiment of the present application enables the crystalline active pattern to have a sudden change point before crystallization, and it is easier for the sudden change point to generate and form seed crystals, thereby enabling the groove to play a role in positioning of crystalline grains during crystallizing to form the crystalline active pattern. Since the groove is defined close to the transition portions, it is conducive to lateral growth of the seed crystals toward the transition portions and the channel before crystallization.

Specifically, as shown in FIG. 1 and FIG. 2, one groove 111a is located at a position where one of the contact portions 1112 is close to the channel 1111. The depth of the groove 111a is equal to the thickness of the crystalline active pattern 111, that is, the groove 111a is a through hole defined close to the channel 1111. Moreover, an orthographic projection of the groove 111a on the substrate 10 is located within an orthographic projection of one of the contact portions 1112 on the substrate 10, and an area of the orthographic projection of the groove 111a on the substrate 10 is less than an area of the orthographic projection of the one of the contact portions 1112 on the substrate 10; that is, the groove 111a does not break the one of the contact portions 1112 into two breaking parts.

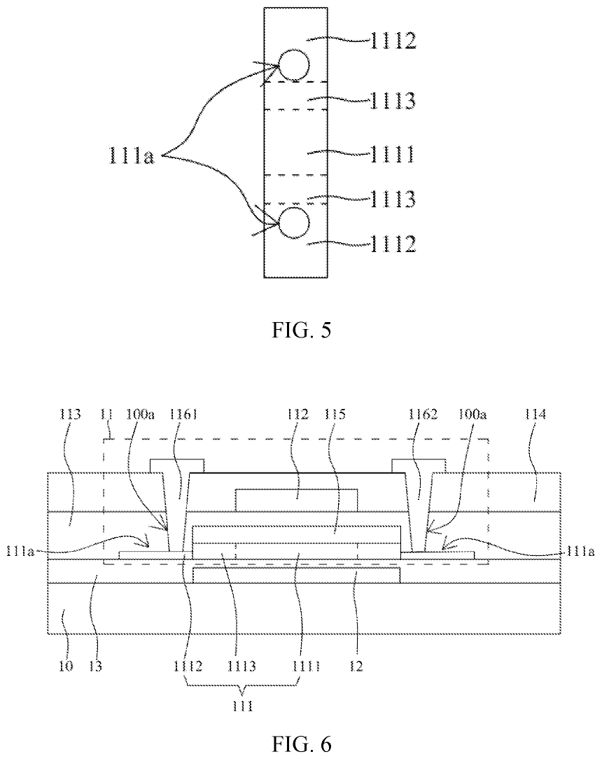

In another embodiment of the present application, as shown in FIG. 4 and FIG. 5, FIG. 4 is a cross-sectional schematic diagram of an array substrate of another embodiment of the present application, and FIG. 5 is a planar schematic diagram of a crystalline active pattern in FIG. 4. Two grooves 111a are located at positions where the two contact portions 1112 close to the channel 1111, respectively. The two grooves 111a are symmetrically defined on the opposite two sides of the channel 1111, and depths of the two grooves 111a are both less than the thickness of the crystalline active pattern 111.

In this embodiment, a cross-sectional shape of the groove 111a along the thickness direction of the crystalline active pattern 111 can be rectangular, trapezoidal, or other shapes. A cross-sectional shape of the groove 111a along the direction perpendicular to the thickness of the crystalline active pattern 111 can be rectangular, circular, or other shapes.

In this embodiment, the heat-retaining layer 115 plays a thermal insulation role, so as to reduce a heat dissipation rate. The heat-retaining layer 115 is in contact with the channel 1111. The heat-retaining layer 115 is located on a surface of the crystalline active pattern 111 away from the substrate 10, but is not limited thereto. The heat-retaining layer 115 can also be located between the crystalline active pattern 111 and the buffer layer 13 and be in contact with a surface of the crystalline active pattern 111 close to the substrate 10.

A thickness of the heat-retaining layer 115 is greater than or equal to 100 Å and is less than or equal to 1000 Å; for example, the thickness of the heat-retaining layer 115 can be 200 Å, 300 Å, 400 Å, 600 Å, 800 Å, or 1000 Å. A preparation material of the heat-retaining layer 115 includes, but is not limited to, silicon oxide.

The heat-retaining layer 115 is in contact with the channel 1111 and the two transition portions 1113, and the heat-retaining layer 115 is not in contact with the two contact portions 1112, so as to reduce a heat dissipation rate of the channel 1111 and the two transition portions 1113 before crystallization and after laser annealing, which is conducive to forming large-sized crystalline grains in the channel 1111 and the two transition portions 1113.

In a process of forming the crystalline active pattern, after annealing and crystallizing an amorphous active pattern by laser, the heat-retaining layer preserves heat for the channel and the two transition portions before crystallization, a heat dissipation rate of a part of the amorphous active pattern where the channel and the two transition portions are to be formed slows down, and the seed crystals generated at the groove grows transversely along the part of the amorphous active pattern where the channel and the two transition portions are to be formed, thereby forming the large-sized crystalline grains in the channel and the two transition portions.

In this embodiment, a refractive index of the heat-retaining layer 115 is defined as n, the thickness of the heat-retaining layer 115 is defined as d, and a wavelength of laser is defined as 2; the n, the d, and the λ satisfy a following formula: 2d×n=k×λ, wherein the k is an integer greater than or equal to 1, and the wavelength λ of the laser is greater than or equal to 180 nm and is less than or equal to 420 nm.

Wherein the wavelength λ of the laser can range from 305 nm to 310 nm, for example, the laser is laser with a wavelength 2 of 308 nm emitted by a XeCl excimer laser device. It can be understood that the wavelength λ of the laser can also range from 185 nm to 200 nm, for example, the laser can also be laser with a wavelength 2 of 193 nm emitted by an ArF excimer laser device; or, the wavelength λ of the laser can also range from 230 nm to 250 nm, for example, the laser can also be laser with a wavelength λ of 248 nm emitted by a KrF excimer laser device.

When the preparation material of the heat-retaining layer 115 is silicon oxide, the refractive index of the heat-retaining layer 115 is 1.6. Wherein a value of the k can be 2, 3, 4, 5, or 6.

The thickness d of the heat-retaining layer in the embodiment of the present application satisfies d=Kλ/(2n), so that during an annealing and crystallization process of the amorphous active pattern using laser with a wavelength of 2, the heat-retaining layer plays an anti-reflection role to the laser, which makes more laser pass through the heat-retaining layer, and the amorphous active pattern under the heat-retaining layer obtains more laser energy and tends to form the larger-sized crystalline grains. Correspondingly, the larger-sized crystalline grains are formed in the channel and the two transition portions, which is conducive to improving the mobility of the thin film transistors, thereby facilitating integration of integrated circuits on insulating substrates.

In this embodiment, due to cooperation of the heat-retaining layer and the groove, the crystalline active pattern 111 includes the crystalline grains with a size greater than or equal to 300 nm; for example, the size of the crystalline grains can be 320 nm, 330 nm, 345 nm, 350 nm, 360 nm, 370 nm, 380 nm, 390 nm, or 400 nm.

In this embodiment, the gate electrode 112 is located on a side of the heat-retaining layer 115 away from the substrate 10. In other words, the thin film transistor 11 is a top-gate thin film transistor. It can be understood that the gate electrode 112 can also be located between the crystalline active pattern 111 and the buffer layer 13, in other words, the thin film transistor 11 is a bottom-gate thin film transistor. The gate electrode 112 is disposed corresponding to the channel 1111. A preparation material of the gate electrode 112 includes, but is not limited to, at least one of molybdenum, aluminum, titanium, copper, and silver.

In this embodiment, the gate insulating layer 113 is disposed between the gate electrode 112 and the heat-retaining layer 115. A preparation material of the gate insulating layer 113 includes, but is not limited to, at least one of silicon nitride and silicon oxide. A thickness of the gate insulating layer 113 is greater than or equal to 500 Å and is less than or equal to 1500 Å; for example, the thickness of the gate insulating layer 113 can be 800 Å, 1000 Å, 1200 Å, 1300 Å, or 1500 Å.

In this embodiment, the gate electrode 112 is located between the crystalline active pattern 111 and the source electrode 1161 and between the crystalline active pattern 111 and the drain electrode 1162. The source electrode 1161 and the drain electrode 1162 are disposed on a same layer, and the source electrode 1161 and the drain electrode 1162 are connected to the two contact portions 1112, respectively. A preparation material of the source electrode 1161 and a preparation material of the drain electrode 1162 include, but are not limited to, at least one of molybdenum, aluminum, titanium, copper, and silver.

In this embodiment, the interlayer insulating layer 114 is located between the crystalline active pattern 111 and the source electrode 1161 and between the crystalline active pattern 111 and the drain electrode 1162, and the interlayer insulating layer 114 is located between the gate electrode 112 and the source electrode 1161 and between the gate electrode 112 and the drain electrode 1162. A preparation material of the interlayer insulating layer 114 includes, but is not limited to, at least one of silicon nitride and silicon oxide. A thickness of the interlayer insulating layer 114 is greater than or equal to 5000 Å and is less than or equal to 6500 Å; for example, the thickness of the interlayer insulating layer 114 can be 5200 Å, 5400 Å, 5500 Å, 5600 Å, or 5800 Å.

In this embodiment, the array substrate 100 further includes two contact holes 100a, and the two contact holes 100a are defined corresponding to the two contact portions 1112, respectively. The two contact holes 100a penetrate through the interlayer insulating layer 114 and the gate insulating layer 113, the source electrode 1161 contacts one of the contact portions 1112 through one of the contact holes 100a, and the drain electrode 1162 contacts another one of the contact portions 1112 through another one of the contact holes 100a.

It can be understood that when the thin film transistor 11 is the bottom-gate thin film transistor, the two contact holes 100a only need to penetrate through the interlayer insulating layer 114.

At least one of the two contact holes 100a overlaps the groove 111a. Specifically, under a case that one groove 111a is defined in one of the contact portions 1112, one of the contact holes 100a overlaps the one groove 111a, and one of the source electrode 1161 and the drain electrode 1162 contacts the one of the contact portions 1112 through the one of the contact holes 100a and the one groove 111a, so that the one of the source electrode 1161 and the drain electrode 1162 forms a ring contact with the one of the contact portion 1112; another one of the source electrode 1161 and the drain electrode 1162 is in contact with a surface of another one of the contact portions 1112 away from the substrate 10 through another one of the contact holes 100a.

It can be understood that in a case that one groove 111a is defined respectively on each of the two contact portions 1112, the two contact holes 100a can overlap two grooves 111a in one-to-one correspondence, the source electrode 1161 forms a ring contact with one of the contact portions 1112 through one of the contact holes 100a and one of the grooves 111a, and the drain electrode 1162 forms a ring contact with another one of the contact portions 1112 through another one of the contact holes 100a and another one of the grooves 111a.

In a case that the groove 111a is defined at a part of a position of the contact portions 1112, an aperture R of the contact holes 100a is larger than an opening size L of the grooves 111a, so that a gate insulating layer located in the grooves 111a can be etched during a process of forming the contact holes 100a, so as to realize communication between the contact holes 100a and the grooves 111a, and further realize connection between one of the source electrode 1161 and the drain electrode 1162 and one of the contact portions 1112.

It can be understood that the two contact holes 100a both can not overlap the grooves 111a. The grooves 111a are defined at the part of the position of the contact portion 1112, and the source electrode 1161 and the drain electrode 1162 are in contact with a part of the contact portions 1112 other than the grooves 111a through the two contact holes 100a.

Please refer to FIG. 6, FIG. 6 is a cross-sectional schematic diagram of an array substrate of yet another embodiment of the present application. The array substrate of this embodiment is basically similar to the array substrate shown in FIG. 4. Similarities will not be described again. Differences include that the depth of the groove 111a is less than the thickness of the crystalline active pattern 111, and the groove 111a located in one of the contact portions 1112 completely overlaps the one of the contact portions 1112. Correspondingly, a step is formed between at least one of the contact portions 1112 and the transition portions 1113.

In this embodiment, the orthographic projection of one groove 111a on the substrate 10 completely coincides with the orthographic projection of one of the contact portions 1112 on the substrate 10. Correspondingly, the area of the orthographic projection of the one groove 111a on the substrate 10 is equal to the area of the orthographic projection of the one of the contact portions 1112 on the substrate 10. Therefore, the groove 111a is formed by thinning the contact portions 1112 in the thickness direction of the crystalline active pattern 111.

In addition, the present application also provides a manufacturing method of an array substrate, which includes following steps:

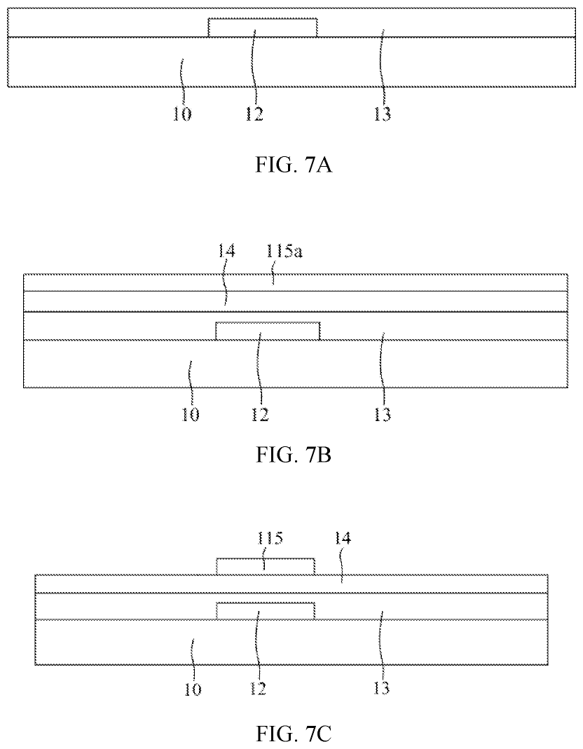

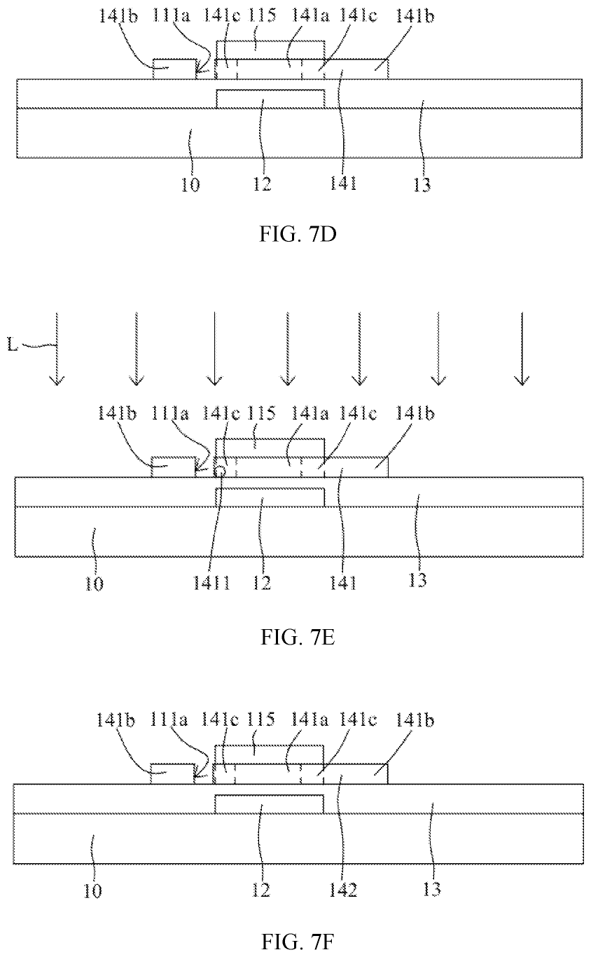

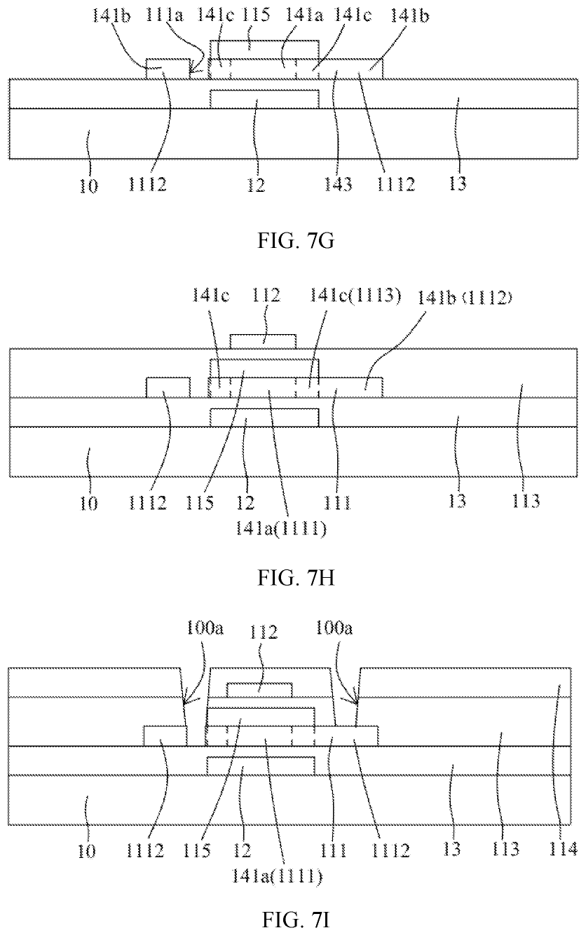

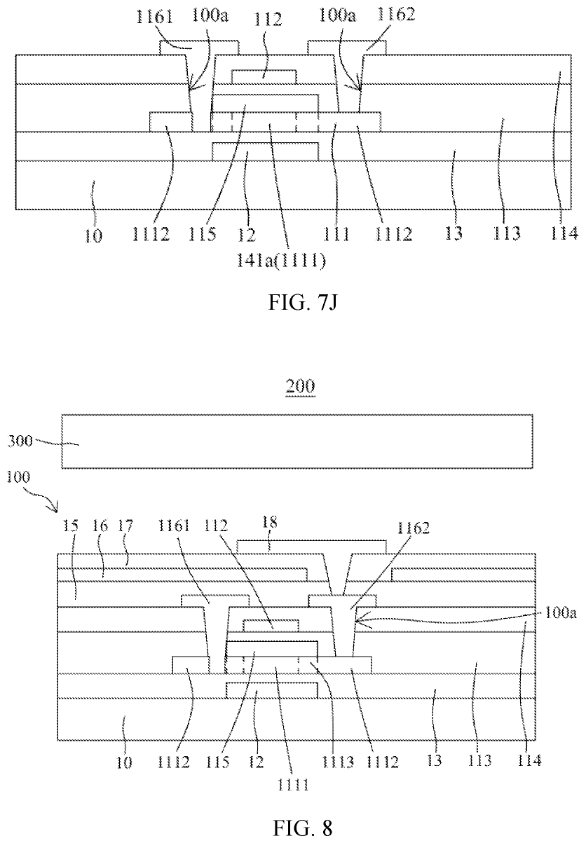

As shown in FIG. 7A, a light shielding metal layer is patterned by a first patterning process to obtain a light-shielding pattern 12 on a substrate 10, and a buffer layer 13 covering the light-shielding pattern 12 and the substrate 10 is formed.

As shown in FIG. 7B, FIG. 7C, and FIG. 7D, an entire amorphous silicon semiconductor layer 14 and an entire heat-retaining film 115a are formed on the buffer layer 13, and the heat-retaining film 115a is patterned by a second patterning process to obtain a heat-retaining layer 115; then, the amorphous silicon semiconductor layer 14 is patterned by a third patterning process to obtain an amorphous silicon semiconductor pattern 141. The amorphous silicon semiconductor pattern 141 has a channel region 141a, two contact regions 141b, and two transition regions 141c. The two contact regions 141b are defined on opposite two sides of the channel region 141a along a direction perpendicular to a thickness of the amorphous silicon semiconductor pattern 141, respectively; one of the transition regions 141c is connected between the channel region 141a and one of the contact regions 141b, the heat-retaining layer 115 overlaps the two transition regions 141c and the channel regions 141a of the amorphous silicon semiconductor pattern 141, and the light-shielding pattern 12 overlaps the two transition regions 141c and the channel regions 141a of the amorphous silicon semiconductor pattern 141. The amorphous silicon semiconductor pattern 141 includes a groove 111a, the groove 111a is defined at a part of a position of one of the contact regions 141b and is defined close to the transition regions 141c, and a depth of the groove 111a is equal to a thickness of the amorphous silicon semiconductor pattern 141.

As shown in FIG. 7E and FIG. 7F, the amorphous silicon semiconductor pattern 141 is annealed by using laser L with a wavelength λ of 308 nm emitted by a XeCl excimer laser device, so as to obtain a polysilicon semiconductor pattern 142. Wherein during a laser annealing process, it is easy for seed crystals 1411 to form at a position where the groove 111a is defined, the amorphous silicon semiconductor pattern 141 located in the two transition regions 141c and the channel region 141a dissipates heat slower under an action of the heat-retaining layer 115. The seed crystals 1411 grow transversely toward the transition regions 141c and the channel region 141a, so that large-sized crystalline grains are easily formed in the transition regions 141c and the channel region 141a.

In addition, when a refractive index n of the heat-retaining layer 115, a thickness d of the heat-retaining layer 115, and a wavelength λ of the laser satisfy a formula 2d×n=k×λ, wherein k is an integer greater than or equal to 1, the heat-retaining layer 115 plays an anti-reflection role to the laser during a process of annealing and crystallization of the amorphous silicon semiconductor pattern 141 by the laser; more laser pass through the heat-retaining layer 115, and the amorphous silicon semiconductor pattern 141 under the heat-retaining layer 115 obtains more laser energy, and tends to form larger-sized crystalline grains; correspondingly, the larger-sized crystalline grains are further formed in the transition regions 141c and the channel region 141a.

As shown in FIG. 7G, the two contact regions 141b of the polysilicon semiconductor pattern 142 are processed by a heavy ion doping process to obtain a heavily doped polysilicon semiconductor pattern 143, and the heavily doped polysilicon semiconductor pattern 143 includes contact portions 1112 disposed in the two contact regions 141b.

As shown in FIG. 7H, a gate insulating layer 113 covering the heavily doped polysilicon semiconductor pattern 143 and the buffer layer 13 is formed, wherein a gate metal layer is patterned on the gate insulating layer 113 by a fourth patterning process to obtain a gate electrode 112. The gate electrode 112 is disposed corresponding to the channel region 141a, the gate electrode 112 is used as a mask, and the two transition regions 141c are processed by a light ion doping process to obtain an crystalline active pattern 111; the crystalline active pattern 111 includes a channel 1111 located in the channel region 141a and transition portions 1113 located in the two transition regions 141c. One of the transition portions 1113 is connected between one of the contact portions 1112 and the channel 1111.

As shown in FIG. 7I, an interlayer insulating layer 114 covering the gate electrode 112 and the gate insulating layer 113 is formed, and the interlayer insulating layer 114 and the gate insulating layer 113 are patterned by a fifth patterning process to obtain two contact holes 100a; the two contact holes 100a are provided corresponding to the two contact portions 1112, and one of the two contact holes 100a communicates with the groove 111a.

As shown in FIG. 7J, a source-drain electrode metal layer is formed on a surface of the interlayer insulating layer 114 away from the gate insulating layer 113, in the two contact holes 100a, and in the groove 111a, and the source-drain electrode metal layer is patterned by a sixth patterning process to obtain a source electrode 1161 and a drain electrode 1162. The source electrode 1161 is in a ring contact with one of the contact portions 1112 through one of the contact holes 100a and the groove 111a, and the drain electrode 1162 is in contact with another one of the contact portions 1112 through another one of the contact holes 100a.

In the manufacturing method of the array substrate according to the embodiment of the present application, by defining the groove in at least one of the two contact regions of the amorphous silicon semiconductor pattern, it is conducive to forming the seed crystals at a position where the groove is located during a process of crystallization of the amorphous silicon semiconductor pattern to form the crystalline active pattern; wherein the seed crystals grow toward the transition regions and the channel region and cooperate with the heat-retaining layer to make heat dissipation of the amorphous silicon semiconductor pattern located in the transition regions and the channel region slower, so as to form the large-sized crystalline grains in the transition regions and the channel region, thereby reducing crystalline boundaries in the channel of the crystalline active pattern, so as to improve the mobility of the thin film transistors.

The present application also provides an electronic device 200. The electronic device 200 is a display panel, and the electronic device 200 can be at least one of a liquid crystal display panel, an organic light emitting diode display panel, a quantum dot light emitting diode display panel, a sub millimeter light emitting diode display panel, and a micron light emitting diode display panel.

Specifically, as shown in FIG. 8, FIG. 8 is a cross-sectional schematic diagram of the electronic device of an embodiment of the present application. The electronic device 200 includes an array substrate 100, a color film substrate 300, and a liquid crystal layer (not shown) disposed between the array substrate 100 and the color film substrate 300. The array substrate 100 is basically similar to the array substrate 100 shown in FIG. 1 and FIG. 2, and similarities are not repeated. Differences include that the array substrate 100 further includes a planarization layer 15, a common electrode 16, a passivation layer 17, and a pixel electrode 18.

Wherein the planarization layer 15 covers the interlayer insulating layer 114, the source electrode 1161, and the drain electrode 1162; the common electrode 16 is disposed on the planarization layer 15, the passivation layer 17 covers the common electrode 16 and the planarization layer 15; the pixel electrode 18 is disposed on the passivation layer 17, and the pixel electrode 18 is connected to the drain electrode 1162 through a via penetrating the passivation layer 17 and the planarization layer 15.

In the electronic device of the embodiment of the present application, by defining the groove in at least one of the two contact portions of the crystalline active pattern, it is conducive to forming the seed crystals at the position where the groove is located during the process of crystallization to form the crystalline active pattern. Wherein the seed crystals grow toward the channel before crystallization and cooperate with the heat-retaining layer to make heat dissipation of the pre-crystallization channel slower, so as to form the large-sized crystalline grains in the channel, thereby reducing the crystalline boundaries in the channel of the crystalline active pattern, so as to improve the mobility of the thin film transistors, which is conducive to realizing the integration of the integrated circuits on the insulating substrates of the electronic device and reducing cost of the electronic device.

The description of the above embodiments is only used to help understand technical schemes and a core idea of the present application. Those of ordinary skill in the art should understand that it is still possible to modify the technical schemes described in the foregoing embodiments, or to equivalently replace some of the technical features. These modifications or substitutions do not make an essence of the corresponding technical schemes depart from a scope of the technical schemes of the embodiments of the present application.

What is claimed is:

1. A thin film transistor, comprising:
a crystalline active pattern, wherein the crystalline active pattern comprises:
a channel;
two contact portions, the two contact portions connected to opposite two sides of the channel in a direction intersecting a thickness direction of the crystalline active pattern; and
at least one groove located on at least one of the two contact portions and extending in the thickness direction of the crystalline active pattern;
a source electrode and a drain electrode connected to the two contact portions, respectively; and
a heat-retaining layer, the heat-retaining layer being in contact with the channel.

2. The thin film transistor according to claim 1, wherein the crystalline active pattern further comprises two transition portions, one of the transition portions is connected between one of the contact portions and the channel, and the heat-retaining layer is further in contact with the two transition portions.

3. The thin film transistor according to claim 1, wherein the crystalline active pattern comprises crystalline grains having a size greater than or equal to 300 nm.

4. The thin film transistor according to claim 1, wherein a refractive index of the heat-retaining layer is defined as n, a thickness of the heat-retaining layer is defined as d, and the n, the d, and a wavelength λ of laser light satisfy a following formula:
2d×n=k×λ, wherein the k is an integer greater than or equal to 1, and the wavelength λ of the laser light is greater than or equal to 180 nm and is less than or equal to 420 nm.

5. The thin film transistor according to claim 1, wherein a thickness of the heat-retaining layer is greater than or equal to 100 Å and is less than or equal to 1000 Å.

6. The thin film transistor according to claim 1, wherein a depth of the groove is less than or equal to a thickness of the crystalline active pattern, and the groove is located at a position of at least one of the contact portions adjacent to the channel.

7. The thin film transistor according to claim 1, wherein a depth of the groove is less than a thickness of the crystalline active pattern, and one groove located on one of the contact portions completely overlaps the one of the contact portions.

8. The thin film transistor according to claim 1, wherein the thin film transistor further comprises:
a gate electrode disposed corresponding to the channel;
a gate insulating layer located between the gate electrode and the crystalline active pattern;
an interlayer insulating layer located between the crystalline active pattern and the source electrode and between the crystalline active pattern and the drain electrode; and
two contact holes at least penetrating the interlayer insulating layer, and the source electrode and the drain electrode being connected to the two contact portions through the two contact holes, respectively.

9. The thin film transistor according to claim 8, wherein the gate electrode is located between the crystalline active pattern and the source electrode and between the crystalline active pattern and the drain electrode, and the interlayer insulating layer is located between the gate electrode and the source electrode and between the gate electrode and the drain electrode; and
the two contact holes further penetrate the gate insulating layer, at least one of the two contact holes overlaps the groove, and an aperture of each of the contact holes is greater than an opening size of the groove.

10. The thin film transistor according to claim 1, wherein the crystalline active pattern is a low-temperature polysilicon active pattern.

11. An electronic device, wherein the electronic device comprises a thin film transistor, and the thin film transistor comprises:
a crystalline active pattern, wherein the crystalline active pattern comprises:
a channel;
two contact portions, the two contact portions connected to opposite two sides of the channel in a direction intersecting a thickness direction of the crystalline active pattern; and
at least one groove located on at least one of the two contact portions and extending in the thickness direction of the crystalline active pattern;
a source electrode and a drain electrode connected to the two contact portions, respectively; and
a heat-retaining layer, the heat-retaining layer being in contact with the channel.

12. The electronic device according to claim 11, wherein the crystalline active pattern further comprises two transition portions, one of the transition portions is connected between one of the contact portions and the channel, and the heat-retaining layer is further in contact with the two transition portions.

13. The electronic device according to claim 11, wherein the crystalline active pattern comprises crystalline grains having a size greater than or equal to 300 nm.

14. The electronic device according to claim 11, wherein a refractive index of the heat-retaining layer is defined as n, a thickness of the heat-retaining layer is defined as d, and the n, the d, and a wavelength λ of laser light satisfy a following formula:
2d×n=k×λ, wherein the k is an integer greater than or equal to 1, and the wavelength λ of the laser light is greater than or equal to 180 nm and is less than or equal to 420 nm.

15. The electronic device according to claim 11, wherein a thickness of the heat-retaining layer is greater than or equal to 100 Å and is less than or equal to 1000 Å.

16. The electronic device according to claim 11, wherein a depth of the groove is less than or equal to a thickness of the crystalline active pattern, and the groove is located at a position of at least one of the contact portions adjacent to the channel.

17. The electronic device according to claim 11, wherein a depth of the groove is less than a thickness of the crystalline active pattern, and one groove located on one of the contact portions completely overlaps the one of the contact portions.

18. The electronic device according to claim 11, wherein the thin film transistor further comprises:
a gate electrode disposed corresponding to the channel;
a gate insulating layer located between the gate electrode and the crystalline active pattern;
an interlayer insulating layer located between the crystalline active pattern and the source electrode and between the crystalline active pattern and the drain electrode; and
two contact holes at least penetrating the interlayer insulating layer, and the source electrode and the drain electrode being connected to the two contact portions through the two contact holes, respectively.

19. The electronic device according to claim 18, wherein the gate electrode is located between the crystalline active pattern and the source electrode and between the crystalline active pattern and the drain electrode, and the interlayer insulating layer is located between the gate electrode and the source electrode and between the gate electrode and the drain electrode; and
the two contact holes further penetrate the gate insulating layer, at least one of the two contact holes overlaps the groove, and an aperture of each of the contact holes is greater than an opening size of the groove.

20. The electronic device according to claim 11, wherein the crystalline active pattern is a low-temperature polysilicon active pattern.
